(19) United States
(12) Patent Application Publication
(10) Pub. No.: US 2024/0210307 A1
(43) Pub. Date: Jun. 27, 2024

(54) MEASURING ARRANGEMENT COMPRISING A MEASURING CELL AND METHOD FOR USING THE MEASURING ARRANGEMENT IN A BIOTECHNOLOGICAL AND/OR PHARMACEUTICAL PROCESS

(71) Applicant: Endress+Hauser Conducta GmbH+Co. KG, Gerlingen (DE)

(72) Inventors: Stefan Paul, Döbeln (DE); Tobias Mieth, Dresden (DE)

(21) Appl. No.: 18/543,626

(22) Filed: Dec. 18, 2023

(30) Foreign Application Priority Data
Dec. 21, 2022 (DE) 10 2022 134 263.8

(51) Int. Cl. G01N 21/15; G01N 21/05

(52) U.S. Cl. CPC G01N 21/15; G01N 21/05; G01N 2021/0125

(57) ABSTRACT

A measuring arrangement for determining a physical process variable, a state variable or a property of the measuring medium, in particular a concentration of one or more components contained in the measuring medium, wherein the measuring arrangement comprises at least one measuring cell having a measuring path and a measuring sensor, wherein the measuring cell comprises a gamma-sterilizable data memory having at least one data set that is specific to a memory cell, and a method for using the measuring arrangement.

### CROSS-REFERENCE TO RELATED APPLICATION

The present application is related to and claims the priority benefit of German Patent Application No. 10 2022 134 263.8, filed on Dec. 21, 2022, the entire contents of which are incorporated herein by reference.

### TECHNICAL FIELD

The present disclosure relates to a measuring arrangement comprising a measuring cell, in particular for single use, and a method for using the measuring arrangement.

### BACKGROUND

Single-use applications have been standard in the field of biotechnology, the pharmaceutical industry and medical technology for some years. Fermentation broths and cell cultivation take place in single-use containers.

The same also applies to the processing of corresponding products in the aforementioned applications in various devices for processing which span, for example, filtration processes, heating and storage. In the case of measuring cells, which are used in particular in optical measurements or photometry, characteristic data, e.g., about the length of the measuring path, which length may have process-related variations, or other data regarding the measuring cell, are typically stored in a data memory.

However, if the measuring cell is designed as a single-use measuring cell, this data changes, for example, if the measuring cells are exchanged. This can result in confusion of the data sets that are individual to the measuring cells.

### SUMMARY

The object of the present disclosure is therefore to establish a concept for the single use of measuring cells, which concept excludes the likelihood of confusion described above.

The present disclosure achieves this object by a measuring arrangement having the features of claim 1, and by a method having the features of claim 14.

The measuring arrangement according to the disclosure serves to determine a physical process variable, a state variable or a property of the measuring medium. A concentration of one or more components contained in the measuring medium can particularly preferably be determined by the measuring arrangement. In particular, the present disclosure relates to the field of application of single-use applications.

The measuring arrangement has at least one measuring cell having a measuring path and a measuring sensor. Furthermore, the measuring cell can also comprise a measuring transducer.

According to the disclosure, the measuring cell has a gamma-sterilizable data memory having at least one data set that is specific to the measuring cell. In Lambert-Beer's law, which describes the basic context of modern photometry, “d” is a layer thickness of the irradiated body. In the case of a measuring cell, this “d” is a function of the length of the measuring path. This length can change as a result of longitudinal expansion and production-related causes. Therefore, the value for each measuring cell is unique. In single-use measuring cells, determining a factor specific to a measuring cell using a reference medium is not possible due to the fact that a sterile surface is specified.

The length of the measuring path must thus be determined exactly and then stored as a characteristic data value. For this purpose, the data memory is provided which, unlike electronics components, withstands gamma irradiation for sterilizing the measuring cell, without substantial functional impairment.

Advantageous developments of the disclosure are the subject matter of the dependent claims.

In order to reduce radiation intensity during gamma sterilization, the gamma-sterilizable data memory is arranged, preferably cast, in the material of the measuring cell rather than on the outside. The data memory is thus surrounded on all sides by the material of the measuring cell.

Furthermore, the measuring arrangement can have a measuring transducer which can be connected to the data memory, preferably via a plug connector, preferably in the form of a readout adapter with a plug interface. This adaptive concept facilitates decoupling and separate sterilization of the measuring cell, without the electronics of the entire measuring arrangement, and also uncomplicated assembly, in particular at the place of use.

In particular, the measuring tube can be provided in a sterile packaging before or in particular also after gamma sterilization and can only be unpacked and mounted at the place of use.

It is advantageous if the plug connector described above is designed both to supply power and to receive data of the data memory. Therefore, the data memory preferably does not have its own power source which can be damaged during gamma sterilization.

Furthermore, the measuring cell can be designed as a flow-through cell. It preferably comprises a measuring medium guide channel, wherein the measuring path crosses the measuring medium guide channel obliquely, preferably perpendicularly.

The measuring path can advantageously be delimited at the terminal by two windows which form a portion of the wall of the measuring cell, wherein the data set specific to the measuring cell comprises at least the length of said measuring path.

The data set stored on the data memory can furthermore comprise information about one or more cross sections of the medium guide channel.

Alternatively or additionally, the data set stored on the data memory can comprise the optical or sound refractive index of both windows and/or the thickness thereof.

Alternatively or additionally, the data set can have a measuring cell constant which is a function of the geometric and/or material-specific properties of the measuring cell.

Advantageously, the data memory can be designed as a silicon chip. As a result, the data memory is particularly robust against radiation.

Furthermore, the measuring transducer and the measuring sensor can be mountable and/or dismountable at the measuring cell without leakage. This facilitates gamma sterilization of the overall system in which the measuring cell is mounted, and subsequent uncomplicated mounting of the further electronics components of the measuring arrangement, without contact with regions that guide the measuring medium.

Moreover, the measuring sensor can have an optical signal transmitter and/or an optical signal receiver for transmitting and/or receiving a signal from the measuring path.

Preferably, the data memory does not have electronics beyond the memory function that could be damaged by gamma sterilization.

A method for using the above-described measuring arrangement, in particular in a biotechnological and/or pharmaceutical process, is also according to the disclosure. The method comprises the following steps:
I. Providing a measuring cell of the measuring arrangement;
II. Gamma radiation treatment of the measuring cell;

The measuring cell or the entire processing system can then be transported packaged in a sterile manner to the place of use.
III. Mounting the measuring sensor and/or the measuring transducer;

Step III can take place in particular after the sterile mounting of the measuring cell in a processing system.
IV. Passing a process medium through the measuring cell, determining a physical process variable, a state variable, and/or a property of the measuring medium, in particular a concentration of at least one component contained in the measuring medium;
Step IV describes a conventional measuring operation of the measuring arrangement, for example a concentration determination, the determination of the optical activity of the measuring medium or the like.
V. Separating the measuring sensor and the measuring transducer from the measuring cell and emptying the measuring medium out of the measuring cell;

Emptying the measuring cell can mean emptying the entire process plant. In single-use applications, at least the parts of the process plant that are in contact with the medium are discarded or disposed of. The measuring transducer and the measuring sensor of the measuring arrangement, on the other hand, can be reused.
VI. Disposing (700) of the measuring cell.

### BRIEF DESCRIPTION OF THE DRAWINGS

In the following, the subject matter of the present disclosure is explained in detail using an exemplary embodiment and with the aid of accompanying figures. In the FIGURES:

FIG. 1 shows a schematic depiction of a measuring arrangement according to the present disclosure.

### DETAILED DESCRIPTION

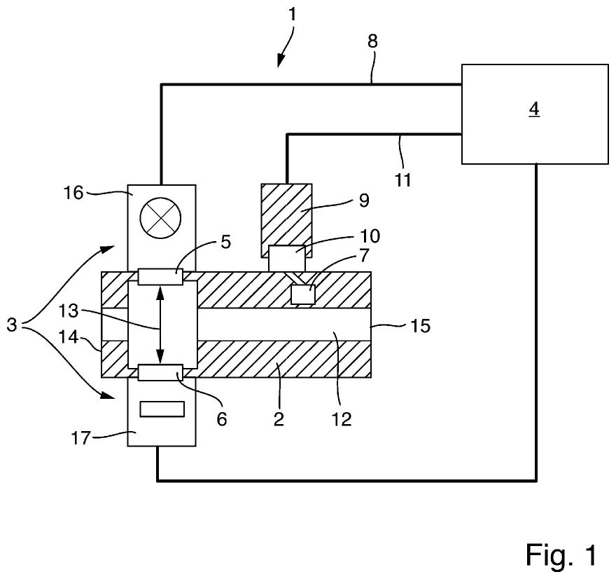

FIG. 1 shows a measuring arrangement 1 according to the present disclosure, preferably a measuring arrangement of process measuring technology, comprising a measuring cell 2, a measuring sensor 3, and a measuring transducer 4.

The measuring cell 2 comprises two windows 5, 6 for feeding a measurement signal in and out.

The distance d of the windows 5, 6 or the distance 2d between the window and the reflection arrangement defines the measuring path within the measuring cell 2.

The window or windows 5, 6 can preferably comprise a material that is indifferent relative to the remaining measuring cell 2. It can, for example, be made of a crystal or glass material. However, a plurality of other materials also comes into consideration.

The measuring sensor 3 is arranged on the window or windows 5, 6. In FIG. 1, the measuring sensor 3 is divided into two components, a signal transmitter 16 and a signal receiver 17. The signal transmitters and receivers are preferably designed to emit and/or receive an optical and/or UV signal. Optical signals are, among other things, fluorescence signals and/or phosphorescence signals. The emitted optical and/or UV signals do not have to correspond to the received signals. For example, an emitted optical signal can excite molecules of the measuring medium to fluorescence and/or phosphorescence, which are detected by the signal receiver.

The operating principle of fluorescence, phosphorescence, UV and/or vis spectroscopy is known per se and has been used for decades. Corresponding configurations of the signal transmitter and of the signal receiver are therefore likewise known. Modules which operate in both transmitting and receiving modes and in which the signal is guided back at a reflection surface are also known.

The measuring sensor 3 can be fixed to the measuring cell 2 in different ways. However, the measuring sensor 3 is preferably fixed detachably to the measuring cell 2 so that the measuring sensor can optionally be mounted and dismounted.

For example, the measuring sensor 3 can be fixed to the measuring cell 2 by means of pipe clamps. So-called clamp-on sensors operate in this way. In this case, adapter structures are fastened by means of the pipe clamps to which the measuring sensors can be fixed, for example by latching or clamping mechanisms. Alternatively, the measuring cell 2 can also have corresponding adapter structures and/or latching elements. These can be integrally bonded to the measuring cell, in particular welded or glued. A preferred adapter structure can be a bayonet mount, wherein the signal transmitter and/or receiver have a bayonet coupling element for correspondence with the receptacle.

To evaluate the determined measurement data of the measuring sensor 3, the measuring transducer 4 is part of the measuring arrangement according to the present disclosure. Typically, the measuring sensor 3 and the measuring transducer 4 form a sensor. The measuring sensor 3 is connected to the measuring transducer 4 via one or more data lines 8, in particular a data cable.

Furthermore, the measuring cell 2 has a gamma-sterilizable data memory 7. Said data memory 7 preferably has no evaluation electronics beyond the memory function. The data memory 7 is preferably a non-volatile memory on which a data set specific to a measuring cell—preferably a geometric data set that is individual to a measuring cell and consists of characteristic data of the measuring cell, particularly preferably comprising at least the length of the measuring path d between the two windows 5 and 6—is stored.

Alternatively or additionally, the data set can also comprise one or more of the following data: serial number of the measuring cell, production date of the measuring cell, order code of the measuring cell, type of connected measuring cell, or of connected single-use device, different standards, such as sealing standards, which are met by the measuring cell,

The measuring sensor and also the readout adapter communicate digitally with the measuring transducer. This allows automatic use of the read-out data during processing of the measured value. The involvement of a user can thereby advantageously be omitted.

The particular advantage of the solution described is the simplicity of the system. Only a connection needs to occur and the readout and evaluation can be carried out by digital processing in a control and evaluation unit of the measuring transducer. Furthermore, the method according to the present disclosure can optionally and advantageously comprise compatibility matching, which is preferably carried out automatically. This makes it possible, for example, to check whether the measuring cell used is compatible with the sensor used. Admittedly, however, this information could also be stored in the QR code.

The data memory can advantageously be a silicon chip. The data memory 7 is advantageously incorporated, for example cast, in the material of the measuring cell 2. This does not result in external damage to the data memory.

In a conventional EEPROM or flash memory, charge carriers (electrons) are stored in the cell. The introduction of radiation can cause this charge to be lost.

Therefore, the data memory 7 used according to the present disclosure is preferably based on storage with the aid of a galvanic connection and not on the storage of charge carriers. Fusible link or PROM is preferred as data memory.

For data processing, the data of the data memory 7 that are specific to a measuring cell are required to evaluate the measurement signal received by the measuring sensor 3 or the measurement signals by the measuring transducer 4.

In order to read the data set of the data memory 7 and to process it together with the measurement data of the measuring sensor, the measuring transducer has a readout adapter 9 with a plug-in connector interface 10.

The readout adapter 9 can preferably be designed as a round plug-in connector since the possibility of shielding the plug-in connection is given here by a metallic sleeve or a screw connection.

For example, one-pole, two-pole or multi-pole plug connectors, for example a so-called Variopin or an M12 plug, can be used for the connection between the measuring cell and the measuring sensor.

The data memory 7 can have one or more connections which correspond to the plug interface 10 of the readout adapter 9. The readout adapter is connected to the measuring transducer 4 via a data line 11. The data line 11 can also be designed as a line for the electrical supply.

The measuring cell 2 is in particular designed as a flow-through cell with a measuring medium guide channel 12 and a measuring path 13 arranged obliquely, preferably perpendicularly thereto, which has the windows 5, 6 at the terminal. Further characteristic data of the measuring cell can be, for example, the flow cross-section of the inlet and outlet opening 14, 15 of the measuring cell.

The flow cross sections and their length can be over the measuring medium guide channel 12 can be part of the characteristic data of a data set of the data memory. Furthermore, the material of the measuring cell, the refractive index, or the thickness of the windows and/or the material thereof can also be part of the characteristic data of a data set of the data memory.

A method for using the measuring arrangement according to the present disclosure is also according to the present disclosure.

The method comprises a first step of providing a measuring cell of a measuring arrangement according to any of the preceding claims.

In this case, the properties can be calibrated and stored in the measuring cell.

In a second step, the gamma sterilization of the measuring cell takes place.

In a third step, the measuring sensor and the measuring transducer are mounted on the measuring cell providing the measuring arrangement according to the present disclosure.

In a fourth step, a physical process variable, a state variable or a property of the measuring medium, such as the concentration of one or more components in the measuring medium, is determined.

Both an amount of substance, a volume concentration, a mass concentration, a particle density and/or an equivalent concentration can be used as the concentration. The determination can comprise determining a specific angle of rotation for determining the optical activity of a solution, for example a sugar solution. The determination can also only comprise monitoring the detection of an agent in the measuring medium. Finally, the determination can also comprise determining a solids content in the measuring medium. The above list is not exhaustive, showing instead only examples which variables can be determined using the device according to the present disclosure.

In a fifth step, the measuring arrangement is emptied and the measuring sensor and the measuring transducer are dismounted from the measuring tube.

In a sixth step, the measuring tube is disposed of, with the measuring sensor and/or the measuring transducer and the readout adapter 9 being reused.

As an alternative to the embodiment described in FIG. 1, the measuring cell can also have only one window and one reflection arrangement, for example an optical or acoustic reflection surface, such as a mirror or the like. In this case, the measurement signal is reflected.

In the case of the variant of the reflection surface (not shown), the measuring sensor can also consist only of a component which can be switched between a signal mode and a reception mode. Ultrasound sensors can, for example, switch between said modes.

1. A measuring arrangement for determining a physical process variable, a state variable, or a property of a measuring medium, including a concentration of one or more components contained in the measuring medium, comprising:
a measuring cell having a measuring path and a measuring sensor; and
a gamma-sterilizable data memory having at least one data set that is specific to a measuring cell.

2. The measuring arrangement according to claim 1, wherein the gamma-sterilizable data memory is arranged in a material of the measuring cell.

3. The measuring arrangement according to claim 1, further comprising:
a measuring transducer which can be connected to the data memory via a readout adapter with a plug interface.

4. The measuring arrangement according to claim 3, wherein the readout adapter is designed to supply power to and receive data from the data memory.

5. The measuring arrangement according to claim 1, wherein the measuring cell is designed as a flow-through cell having a measuring medium guide channel, wherein the measuring path crosses the measuring medium guide channel obliquely.

6. The measuring arrangement according to claim 5, wherein the measuring path is delimited at a terminal by two windows which form a portion of the wall of the measuring cell, wherein the data set that is specific to a measuring cell includes at least a length of the measuring path.

7. The measuring arrangement according to claim 5, wherein the data set has one or more cross sections of the medium guide channel.

8. The measuring arrangement according to claim 6, wherein the data set includes an optical or a sound refractive index of both windows and/or a thickness thereof.

9. The measuring arrangement according to claim 1, wherein the data set includes a measuring cell constant which is a function of a geometric and/or material-specific properties of the measuring cell.

10. The measuring arrangement according to claim 1, wherein the data memory is designed as a silicon chip.

11. The measuring arrangement according to claim 3, wherein the measuring transducer and the measuring sensor can be mounted and/or dismounted from the measuring cell without leakage.

12. The measuring arrangement according to claim 1, wherein the measuring sensor includes an optical signal transmitter and/or an optical signal receiver for transmitting and/or receiving a signal from the measuring path.

13. The measuring arrangement according to claim 1, wherein the data memory within the measuring cell is not connected to any electronics beyond the memory function.

14. A method for using a measuring arrangement in a biotechnological and/or pharmaceutical process, comprising:
I. providing a measuring arrangement, including:
a measuring cell having a measuring path and a measuring sensor;
a gamma-sterilizable data memory having at least one data set that is specific to a measuring cell; and
a measuring transducer which can be connected to the data memory via a readout adapter with a plug interface;
II. treating the measuring cell with gamma radiation;
III. mounting the measuring sensor and/or the measuring transducer;
IV. passing a process medium through the measuring cell and determining a physical process variable, a state variable, and/or a property of the measuring medium, including a concentration of at least one component contained in the measuring medium;
V. separating the measuring sensor and the measuring transducer from the measuring cell and emptying the measuring medium out of the measuring cell; and
VI. disposing of the measuring cell.

15. The method according to claim 14, wherein the measuring cell is provided according to step I or is transported to the place of use in sterile packaging following step II.
